(19) United States
(12) Patent Application Publication
(10) Pub. No.: US 2025/0356094 A1
(43) Pub. Date: Nov. 20, 2025

(54) SYSTEM AND METHOD FOR ESTIMATING SEMICONDUCTOR DEVICE

(71) Applicant: TAIWAN SEMICONDUCTOR MANUFACTURING COMPANY, LTD., Hsinchu (TW)

(72) Inventors: Fangyi CHANG, Keelung City (TW); Yu-Sheng LU, New Taipei City (TW); Cheng-Yuan WANG, Hsinchu (TW); Hung-Chih OU, Kaohsiung City (TW)

(73) Assignee: TAIWAN SEMICONDUCTOR MANUFACTURING COMPANY, LTD., Hsinchu (TW)

(21) Appl. No.: 18/666,494

(22) Filed: May 16, 2024

(51) Int. Cl. G06F 30/337

(52) U.S. Cl. CPC G06F 30/337

(57) ABSTRACT

A method includes: generating a distribution pattern according to driving sizes of logic gates of a first semiconductor device corresponding to first data; transforming the distribution pattern to distribution data; generating first characterization data of the first semiconductor device according to the first data; generating first estimated distribution data according to the first characterization data by a model; training the model according to the first estimated distribution data and the distribution data; and processing second characterization data by the trained model to generate second estimated distribution data. The second characterization data corresponds to a second semiconductor device different from the first semiconductor device.

### BACKGROUND

Before manufacturing a semiconductor device, engineer change order (ECO) swapping simulation is performed to data corresponding to the semiconductor device. Very large scale integration (VLSI) cells are swapped automatically in final automatic placement and routing (APR) stage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart diagram of a method of estimating data associated with a semiconductor device, in accordance with some embodiments of the present disclosure.

FIG. 2 is a schematic diagram of a bar chart and a table associated with the operation shown in FIG. 1, in accordance with some embodiments of the present disclosure.

FIG. 3 is a schematic diagram of a system performing the operation shown in FIG. 1, in accordance with some embodiments of the present disclosure.

FIG. 4 is a schematic diagram of the system performing the operation shown in FIG. 1, in accordance with some embodiments of the present disclosure.

FIG. 5 is a flowchart diagram of a method corresponding to the system shown in FIG. 3 and FIG. 4, in accordance with some embodiments of the present disclosure.

FIG. 6 is a flowchart diagram of a method corresponding to the system shown in FIG. 3 and FIG. 4, in accordance with some embodiments of the present disclosure.

FIG. 7 is a schematic view of a system for performing at least one of the methods shown in FIG. 1, FIG. 5 and FIG. 6, in accordance with some embodiments of the present disclosure.

FIG. 8 is a block diagram of an integrated circuit (IC)/semiconductor device manufacturing system, and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

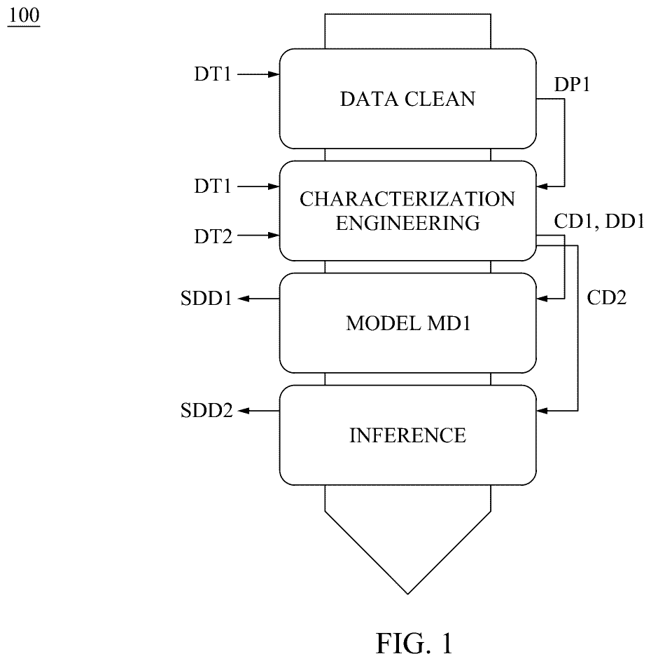

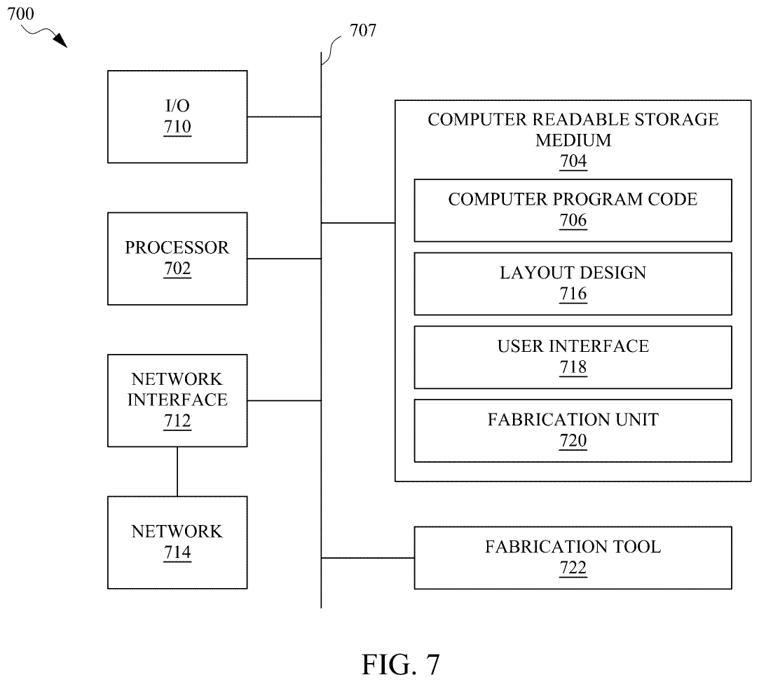

FIG. 1 is a flowchart diagram of a method 100 of estimating data associated with a semiconductor device, in accordance with some embodiments of the present disclosure. In some embodiments, the method 100 is performed by a processor, such as the processor 702 shown in FIG. 7. As illustratively shown in FIG. 1, the method 100 includes operations OP11-OP14.

During the operation OP11, a data clean operation is performed to data DT1 to generate a distribution pattern DP1. In some embodiments, the data DT1 corresponds to a timing report of the existing automatic placement and routing (APR) databases. The distribution pattern DP1 includes factors associated with quantities of gate types of a semiconductor device corresponding to the data DT1.

For example, in some embodiments, the distribution pattern DP1 includes Table 1 shown as following.

TABLE 1

| Gate type | Count |
|---|---|
| TP1 | CT1 |
| TP2 | CT2 |
| TP3 | CT3 |
| TP4 | CT4 |

As shown in Table 1, the gate types TP1-TP4 correspond to counts CT1-CT4, respectively. The counts CT1-CT4 are quantities of logic gates of the gate types TP1-TP4 in the semiconductor device corresponding to the data DT1.

For example, the gate type TP1 corresponds to NAND logic gate. The gate type TP2 corresponds to buffers having a first driving size. The gate type TP3 corresponds to buffers having a second driving size different from the first driving size. The gate type TP4 corresponds to inverters. The counts CT1-CT4 are 4, 1, 3 and 1, respectively. In such example, the semiconductor device corresponding to the data DT1 includes four NAND logic gates, one buffer having the first driving size, three one buffer having the second driving size and one inverter. However, the embodiments of present disclosure are not limited to this. In various embodiments, various counts and various gate types are included in the table 1.

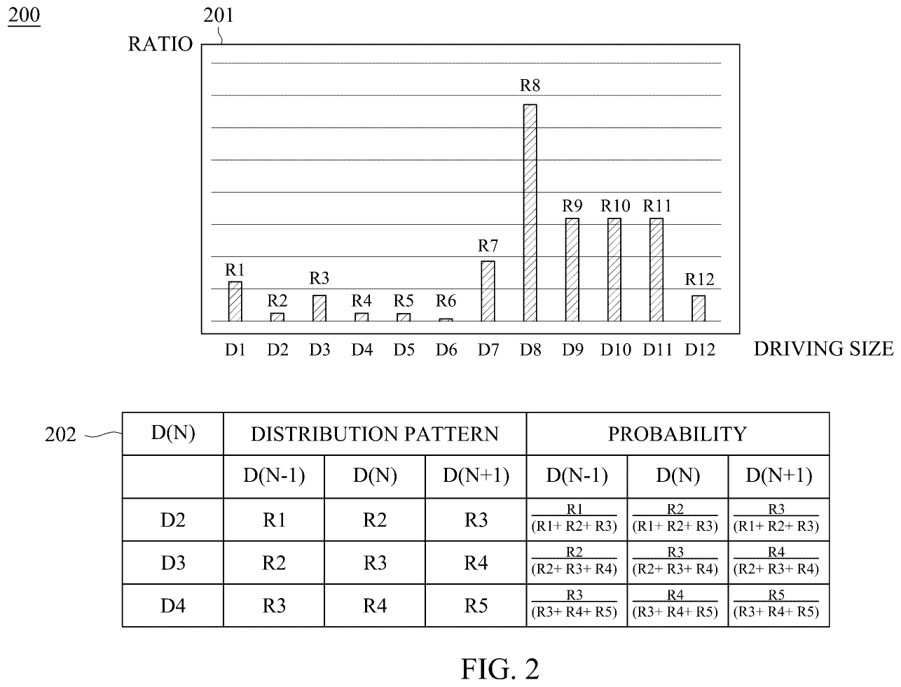

During the operation OP12, a characterization engineering operation is performed to generate characterization data CD1 and distribution data DD1. In some embodiments, the processor is configured to identify significant factors, such as energy consumption or delay, from the data DT1, to generate the characterization data CD1. In some embodiments, the processor is configured to transform the distribution pattern DP1 into the distribution data DD1 which includes a series of probability numerical values for each logic gate family. Further details of the characterization data CD1 and the distribution data DD1 are described below with the embodiments associated with FIG. 2.

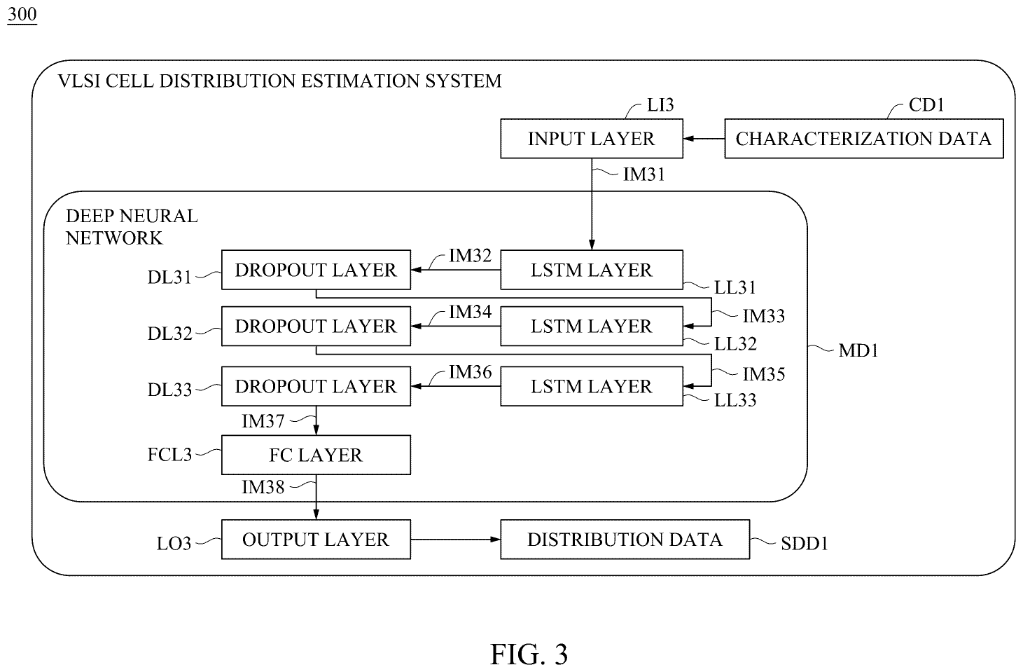

During the operation OP13, a model MD1 is trained according to the characterization data CD1 and the distribution data DD1 by a cell distribution estimation system, such as the system 300 shown in FIG. 3. Specifically, the model MD1 is configured to generate estimated distribution data SDD1 according to the characterization data CD1. The processor is configured to compare the estimated distribution data SDD1 and the distribution data DD1 to train the model MD1. In some embodiments, the distribution data DD1 and the estimated distribution data SDD1 are referred to as very large scale integration (VLSI) cell distribution data of the semiconductor device corresponding to the data DT1.

For example, the processor generates a loss function according to a difference between the estimated distribution data SDD1 and the distribution data DD1, and adjusts weights of the model MD1 to decrease the loss function. In some embodiments, the training stops when the loss function has a minimum value. Further details of the model MD1 are described below with the embodiments associated with FIG. 3.

In some embodiments, after the model MD1 is trained, the operating OP12 is performed to data DT2 to generate corresponding characterization data CD2. The data DT2 corresponds to a new semiconductor device different from the semiconductor device corresponding to the data DT1.

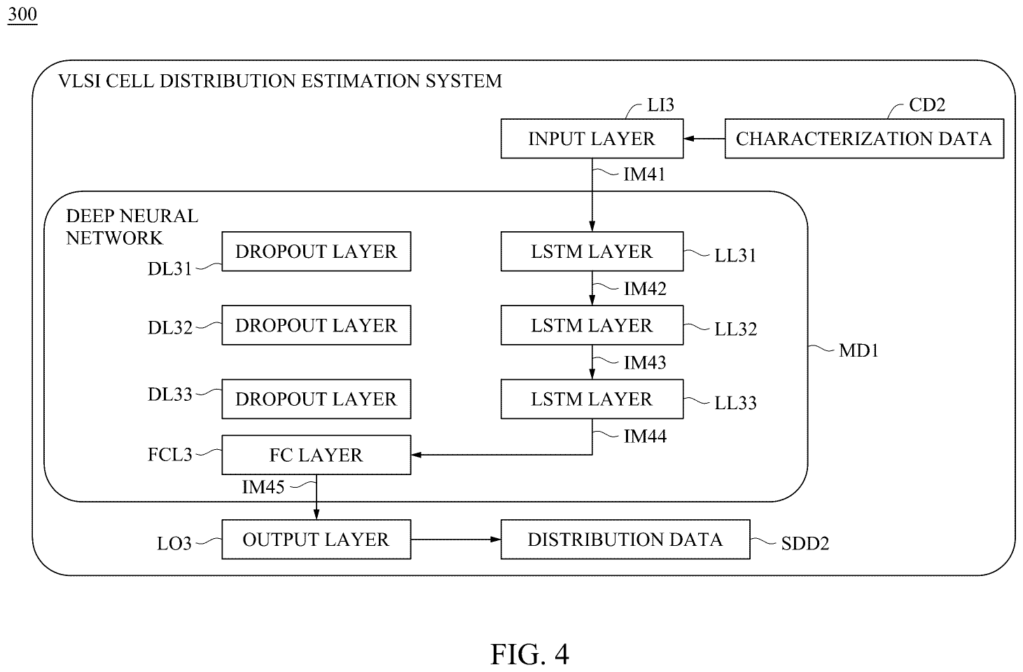

During the operation OP14, an inference operation is performed to the characterization data CD2 to generate estimated distribution data SDD2. Specifically, the processor is configured to process the characterization data CD2 by the model MD1 to generate the estimated distribution data SDD2. Accordingly, the characterization data CD2 is estimated by the model MD1 to generate the estimated distribution data SDD2. In some embodiments, the estimated distribution data SDD2 is referred to as VLSI cell distribution data of the semiconductor device corresponding to the data DT2. Further details of the model MD1 are described below with the embodiments associated with FIG. 4.

In some embodiments, after the operation OP14, the processor is configured to generate a leakage power value according to the estimated distribution data SDD2, and compare the leakage power value with a preset leakage power value. When the leakage power value is smaller than the preset leakage power value, a manufacturing device is configured to manufacture the semiconductor device corresponding to the data DT2. When the leakage power value is larger than or equal to the preset leakage power value, the processor is configured to adjust the data DT2, and perform the operation OP14 again, until the leakage power value is smaller than the preset leakage power value. After the leakage power value is smaller than the preset leakage power value, the semiconductor device is manufactured according to the adjusted data DT2. Accordingly, the semiconductor device satisfying the requirement of the preset leakage power value is manufactured after performing the method 100. In some embodiments, the leakage power value corresponds to performance per watt (PPW) metric.

In some approaches, the PPW gain is derived by APR tools, which requires long turn-around time for each library or any specification update. Furthermore, the APR tools for the advance node are under development and not mature enough. The guideline or the expected goal is needed to evaluate the APR tools results.

Compared to above approaches, in some embodiments of the present disclosure, the method 100 is performed to estimate the PPW metric. The data DT2 corresponding to the advanced manufacturing node is estimated in the early manufacturing exploration stage by leveraging the data DT1 which corresponds to the existing design databases and VLSI libraries. Accordingly, a faster, less storage usage and commercial licenses free methodology providing a faster assessment review for any VLSI library change in a very early stage is achieved by the method 100.

FIG. 2 is a schematic diagram of a bar chart 201 and a table 202 associated with the operation OP12 shown in FIG. 1, in accordance with some embodiments of the present disclosure. For illustration purpose, the bar chart 201 and the table 202 correspond to buffers in the semiconductor device corresponding to the data DT1. Features of bar charts and tables corresponding to other logic gates, such as inverters or NAND gates, are similar with features the bar chart 201 and the table 202.

As illustratively shown in FIG. 2, a horizontal axis of the bar chart 201 corresponds to driving sizes of the buffers. The buffers have driving sizes D1-D12 arranged in order. When a buffer has a larger driving size, a pin capacitance, an area and an energy consumption of the buffer are larger.

For example, the driving size D2 is larger than the driving size D1. Accordingly, a pin capacitance of the buffers having the driving size D2 is larger than a pin capacitance of the buffers having the driving size D1. An area of the buffers having the driving size D2 is larger than an area of the buffers having the driving size D1. An energy consumption of the buffers having the driving size D2 is larger than an energy consumption of the buffers having the driving size D1.

As illustratively shown in FIG. 1, a vertical axis of the bar chart 201 corresponds to ratios of quantities of the buffers of corresponding driving sizes. The buffers having the driving sizes D1-D12 have ratios R1-R12, respectively. Specifically, the ratio R1 is equal to a quantity of the buffers having the driving size D1 divided by a quantity of the logic gates of the semiconductor corresponding to the data DT1. The ratio R2 is equal to a quantity of the buffers having the driving size D2 divided by the quantity of the logic gates of the semiconductor corresponding to the data DT1, and so on. The ratio R12 is equal to a quantity of the buffers having the driving size D12 divided by the quantity of the logic gates of the semiconductor corresponding to the data DT1.

In some embodiments, the table 202 is generated according to the bar chart 201. The table 202 includes portions P21 and P22. The portion P21 corresponds to the distribution pattern DP1 and includes the ratios R1-R12. The portion P22 includes probability numerical values which are calculated according to the ratios R1-R12.

Referring to FIG. 1 and FIG. 2, for the embodiment shown in FIG. 2, the distribution pattern DP1 includes the ratios R1-R12, and the distribution data DD1 includes the probability numerical values of the portion P22.

In some embodiments, for N being a positive integer, probability numerical values Y1(N), Y2(N) and Y3(N) are calculated according to the distribution pattern DP1. Referring to FIG. 1 and FIG. 2, the distribution data DD1 includes the probability numerical values Y1(N), Y2(N) and Y3(N) for each N.

In some embodiments, the probability numerical values Y1(N), Y2(N) and Y3(N) are evaluated according to the ratios R(N), R(N−1) and R(N+1). Specifically, the probability numerical values Y1(N), Y2(N) and Y3(N) are calculated by following equations:

$$Y 1 ( N ) = \frac{R ( N - 1 )}{R ( N - 1 ) + R ( N ) + R ( N + 1 )} ; \\ Y 2 ( N ) = \frac{R ( N )}{R ( N - 1 ) + R ( N ) + R ( N + 1 )} ; \\ Y 3 ( N ) = \frac{R ( N + 1 )}{R ( N - 1 ) + R ( N ) + R ( N + 1 )} .$$

For example, regarding the driving size D2, corresponding probability numerical values Y1(N), Y2(N) and Y3(N) are calculated by:

$$Y 1 ( 2 ) = \frac{R 1}{R 1 + R 2 + R 3} ; \\ Y 2 ( 2 ) = \frac{R 2}{R 1 + R 2 + R 3} ; \\ Y 3 ( 2 ) = \frac{R 3}{R 1 + R 2 + R 3} .$$

On the other hand, referring to FIG. 1, during the operation OP12, the processor is further configured to generate a series of sequences X(N) for each driving size with the same logic family (for example, the buffers, the inverters and NAND gates). The characterization data CD1 includes the collection of the sequences X(N).

The sequences X(N) include factors PC(N−1), EN(N−1), LK(N−1), PC(N), EN(N), LK(N), PC(N+1), EN(N+1) and LK(N+1). The factor PC(N) corresponds to a pin capacitance of the buffers having the driving size D(N). The factor EN(N) corresponds to an energy consumption of the buffers having the driving size D(N). The factor LK(N) corresponds to an energy leakage of the buffers having the driving size D(N).

For example, sequences X(2) include factors PC(1), EN(1), LK(1), PC(2), EN(2), LK(2), PC(3), EN(3) and LK(3). The factors PC(1), EN(1), LK(1) correspond to a pin capacitance, an energy consumption and an energy leakage, respectively, of the buffers having the driving size D1. The factors PC(2), EN(2), LK(2) correspond to a pin capacitance, an energy consumption and an energy leakage, respectively, of the buffers having the driving size D2. The factors PC(3), EN(3), LK(3) correspond to a pin capacitance, an energy consumption and an energy leakage, respectively, of the buffers having the driving size D3.

In some embodiments, for the largest N and the smallest N, the factors are used repeatedly. For example, in the embodiment shown in FIG. 2, the largest N and smallest N are 12 and 1, respectively. Accordingly, the sequences X(1) include factors PC(1), EN(1), LK(1), PC(1), EN(1), LK(1), PC(2), EN(2) and LK(2). The sequences X(1) include factors PC(11), EN(11), LK(11), PC(12), EN(12), LK(12), PC(12), EN(12) and LK(12).

Similarly, for the largest N and the smallest N, the ratios are used repeatedly for the probability numerical values Y1(N), Y2(N) and Y3(N). For example, in the embodiment shown in FIG. 2, the denominator of the probability numerical values Y1(1), Y2(1) and Y3(1) is R1+R1+R2, and the denominator of the probability numerical values Y1(12), Y2(12) and Y3(12) is R11+R12+R12.

In some embodiments, during the operation OP13, the model MD1 is trained by treating the sequences X(N) as the input value and treating the probability numerical values Y1(N), Y2(N) and Y3(N) as the labeled output.

FIG. 3 is a schematic diagram of a system 300 performing the operation OP13 shown in FIG. 1, in accordance with some embodiments of the present disclosure. In some embodiments, the system 300 is referred to as a VLSI cell distribution estimation system. As illustratively shown in FIG. 3, the system 300 includes an input layer LI3, an output layer LO3 and the model MD1.

In some embodiments, the model MD1 is implemented by a deep neural network. In some embodiments, the system 300 includes a processor (such as the processor 702 shown in FIG. 7) and a memory (such as the computer readable storage medium 704 shown in FIG. 7), in which the processor is configured to operate the input layer LI3, the output layer LO3 and the model MD1, and the memory is configured to store weights of the model MD1.

In some embodiments, the input layer LI3 is configured to receive the characterization data CD1, and generate input data IM31 according to the characterization data CD1. The model MD1 is configured to process the input data IM31 to generate the output data IM38. The output layer LO3 is configured to generate the estimated distribution data SDD1 according to the output data IM38.

As illustratively shown in FIG. 3, the model MD1 includes three long short-term memory (LSTM) layers LL31-LL33, three dropout layers DL31-DL33 and a full connected (FC) layer FCL3. The LSTM layer LL31 is configured to generate intermediate data IM32 according to the input data IM31. The dropout layer DL31 is configured to generate intermediate data IM33 according to the intermediate data IM32. The LSTM layer LL32 is configured to generate intermediate data IM34 according to the intermediate data IM33. The dropout layer DL32 is configured to generate intermediate data IM35 according to the intermediate data IM34. The LSTM layer LL33 is configured to generate intermediate data IM36 according to the intermediate data IM35. The dropout layer DL33 is configured to generate intermediate data IM37 according to the intermediate data IM36. Alternatively stated, the input data IM31 is processed by the LSTM layers LL31-LL33 and the dropout layers DL31-DL33 alternately to generate the intermediate data IM37. The FC layer FCL3 is configured to generate the output data IM38 according to the intermediate data IM37.

In some embodiments, the system 300 is further configured to compare the estimated distribution data SDD1 and the distribution data DD1, and adjust weights of the model MD1 according to the comparison result. For example, the system 300 generates a loss function according to a difference between the estimated distribution data SDD1 and the distribution data DD1, and adjusts the weights of the LSTM layers LL31-LL33 and the FC layer FCL3 to decrease the loss function. Accordingly, the model MD1 is trained according to the estimated distribution data SDD1 and the distribution data DD1.

FIG. 4 is a schematic diagram of the system 300 performing the operation OP14 shown in FIG. 1, in accordance with some embodiments of the present disclosure. Referring to FIG. 1, FIG. 3 and FIG. 4, the operation OP14 corresponding to FIG. 4 is performed after the model MD1 is trained by the operation OP13 corresponding to FIG. 3.

As illustratively shown in FIG. 4, the input layer LI3 is configured to receive the characterization data CD2, and generate input data IM41 according to the characterization data CD2. In some embodiments, the characterization data CD2 includes sequences similar to the sequences X(N). For example, the processor select pin capacitances, energy consumptions and energy leakages corresponding to different driving sizes and different logic families from the data DT2, to generate the sequences in the characterization data CD2.

In some embodiments, the LSTM layer LL31 is configured to generate intermediate data IM42 according to the input data IM41. The LSTM layer LL32 is configured to generate intermediate data IM43 according to the intermediate data IM42. The LSTM layer LL33 is configured to generate intermediate data IM44 according to the intermediate data IM43. The FC layer FCL3 is configured to generate the output data IM45 according to the intermediate data IM44. The output layer LO3 is configured to generate the estimated distribution data SDD2 according to the output data IM45.

In some embodiments, the dropout layers DL31-DL33 are skipped during the operation OP14. Alternatively stated, the characterization data CD2 is processed by the LSTM layers LL31-LL33 and does not processed by the dropout layers DL31-DL33. The model MD1 processes the characterization data CD2 without processing by the dropout layers DL31-DL33, to generate the estimated distribution data SDD2.

Referring to FIG. 1 and FIG. 4, the processor is configured to determine whether the semiconductor corresponding to the data DT2 is manufactured according to the estimated distribution data SDD2. For example, when a leakage power value corresponding to the estimated distribution data SDD2 is larger than or equal to a preset leakage power value, the data DT2 is adjusted and the estimated distribution data SDD2 is changed accordingly. When the leakage power value smaller than the preset leakage power value, the semiconductor corresponding to the data DT2 is manufactured by the manufacturing device.

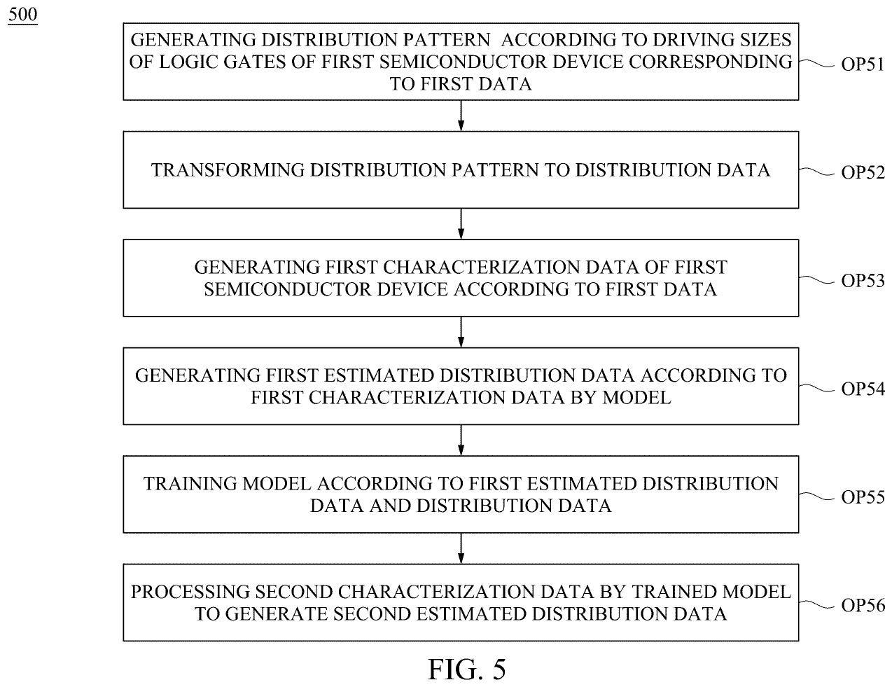

FIG. 5 is a flowchart diagram of a method 500 corresponding to the system 300 shown in FIG. 3 and FIG. 4, in accordance with some embodiments of the present disclosure. As illustratively shown in FIG. 5, the method 500 includes operations OP51-OP56.

During the operations OP51, the system 300 generates the distribution pattern DP1 according to the driving sizes of logic gates of the semiconductor device corresponding to the data DT1. For example, the system 300 generates the distribution pattern DP1 according to the driving sizes D1-D12 of the buffers.

During the operations OP52, the system 300 transforms the distribution pattern DP1 to the distribution data DD1.

During the operations OP53, the system 300 generates the characterization data CD1 of the semiconductor device according to the data DT1.

During the operations OP54, the system 300 generates the estimated distribution data SSD1 according to the characterization data CD1 by the model MD1.

During the operations OP55, the system 300 trains the model MD1 according to the estimated distribution data SSD1 and the distribution data DD1.

During the operations OP56, the system 300 processes characterization data CD2 by the trained model MD1 to generate estimated distribution data SSD2. In some embodiments, the characterization data CD2 corresponds to the semiconductor device different from the semiconductor device corresponding to the data DT1.

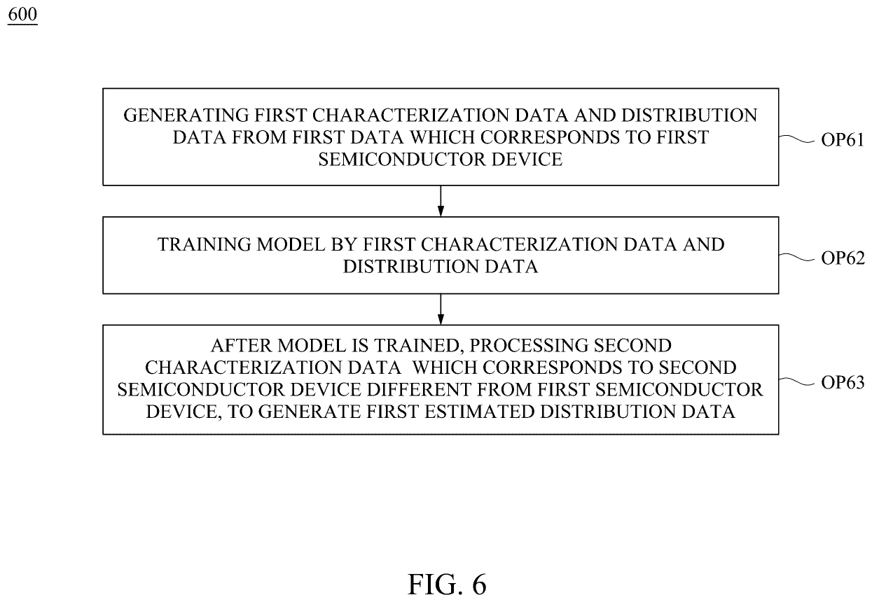

FIG. 6 is a flowchart diagram of a method 600 corresponding to the system 300 shown in FIG. 3 and FIG. 4, in accordance with some embodiments of the present disclosure. As illustratively shown in FIG. 6, the method 600 includes operations OP61-OP63.

During the operations OP61, the system 300 generates the characterization data CD1 and the distribution data DD1 from the data DT1.

During the operations OP62, the system 300 trains the model MD1 by the characterization data CD1 and the distribution data DD1.

During the operations OP63, after the model MD1 is trained, the system 300 processes the characterization data CD2 which corresponds to the semiconductor device different from the semiconductor device of the data DT1, to generate estimated distribution data SSD2. In some embodiments, characterization data CD1 is associated with pin capacitances, energy consumptions and energy leakages of the semiconductor device of the data DT1, and the distribution data DD1 is associated with driving sizes of logic gates of the semiconductor device of the data DT1. For example, the distribution data DD1 is associated with the driving sizes D1-D12 of the buffers.

FIG. 7 is a schematic view of a system 700 for performing at least one of the methods 100, 500 and 600 shown in FIG. 1, FIG. 5 and FIG. 6, in accordance with some embodiments of the present disclosure. The system 700 generates or places one or more IC layout designs corresponding to at least one of the data DT1 and DT2, as described herein. In some embodiments, the system 700 manufactures one or more semiconductor devices based on the one or more IC layout designs, as described herein. The system 700 includes a hardware processor 702 and a non-transitory, computer readable storage medium 704 encoded with, e.g., storing, the computer program code 706, e.g., a set of executable instructions. The computer readable storage medium 704 is configured for interfacing with manufacturing machines for producing the semiconductor device. The processor 702 is electrically coupled to the computer readable storage medium 704 by a bus 707. The processor 702 is also electrically coupled to an I/O interface 710 by the bus 707. A network interface 712 is also electrically connected to the processor 702 by the bus 707. Network interface 712 is connected to a network 714, so that the processor 702 and the computer readable storage medium 704 are capable of connecting to external elements via network 714. The processor 702 is configured to execute the computer program code 706 encoded in the computer readable storage medium 704 in order to cause the system 700 performing at least one of the methods 100, 500 and 600.

In some embodiments, the processor 702 is a central processing unit (CPU), a multi-processor, a distributed processing system, an application specific integrated circuit (ASIC), and/or a suitable processing unit.

In some embodiments, the computer readable storage medium 704 is an electronic, magnetic, optical, electromagnetic, infrared, and/or a semiconductor system (or apparatus or device). For example, the computer readable storage medium 704 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 704 includes a compact disk-read only memory (CD-ROM), a compact disk-read/write (CD-R/W), and/or a digital video disc (DVD).

In some embodiments, the storage medium 704 also stores information needed for performing at least one of the methods 100, 500 and 600, such as layout design 716, user interface 718, fabrication unit 720, and/or a set of executable instructions to perform at least one of the methods 100, 500 and 600.

In some embodiments, the storage medium 704 stores instructions (e.g., the computer program code 706) for interfacing with manufacturing machines. The instructions (e.g., the computer program code 706) enable the processor 702 to generate manufacturing instructions readable by the manufacturing machines to effectively implement the semiconductor devices of the data DT1 and DT2.

The system 700 includes the I/O interface 710. The I/O interface 710 is coupled to external circuitry. In some embodiments, the I/O interface 710 includes a keyboard, keypad, mouse, trackball, trackpad, and/or cursor direction keys for communicating information and commands to the processor 702.

The system 700 also includes the network interface 712 coupled to the processor 702. The network interface 712 allows the system 700 to communicate with the network 714, to which one or more other computer systems are connected. The network interface 712 includes wireless network interfaces such as BLUETOOTH, WIFI, WIMAX, GPRS, or WCDMA; or wired network interface such as ETHERNET, USB, or IEEE-13154. In some embodiments, at least one of the methods 100, 500 and 600 is implemented in two or more systems 700, and information such as layout design, user interface and fabrication unit are exchanged between different systems 700 by the network 714.

The system 700 is configured to receive information related to a layout design through the I/O interface 710 or network interface 712. The information is transferred to the processor 702 by the bus 707 to determine a layout design for producing an IC. The layout design is then stored in the computer readable medium 704 as the layout design 716. The system 700 is configured to receive information related to a user interface through the I/O interface 710 or network interface 712. The information is stored in the computer readable medium 704 as the user interface 718. The system 700 is configured to receive information related to a fabrication unit through the I/O interface 710 or network interface 712. The information is stored in the computer readable medium 704 as the fabrication unit 720. In some embodiments, the fabrication unit 720 includes fabrication information utilized by the system 700.

In some embodiments, at least one of the methods 100, 500 and 600 is implemented as a standalone software application for execution by a processor. In some embodiments, at least one of the methods 100, 500 and 600 is implemented as a software application that is a part of an additional software application. In some embodiments, at least one of the methods 100, 500 and 600 is implemented as a plug-in to a software application. In some embodiments, at least one of the methods 100, 500 and 600 is implemented as a software application that is a portion of an EDA tool. In some embodiments, at least one of the methods 100, 500 and 600 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, the semiconductor devices of the data DT1 and DT2 is implemented by a manufacturing device to manufacture an integrated circuit using a set of masks manufactured based on one or more layout designs generated by the system 700. In some embodiments, the system 700 includes a manufacturing device (e.g., fabrication tool 722) to manufacture an integrated circuit using a set of masks manufactured based on one or more layout designs of the present disclosure.

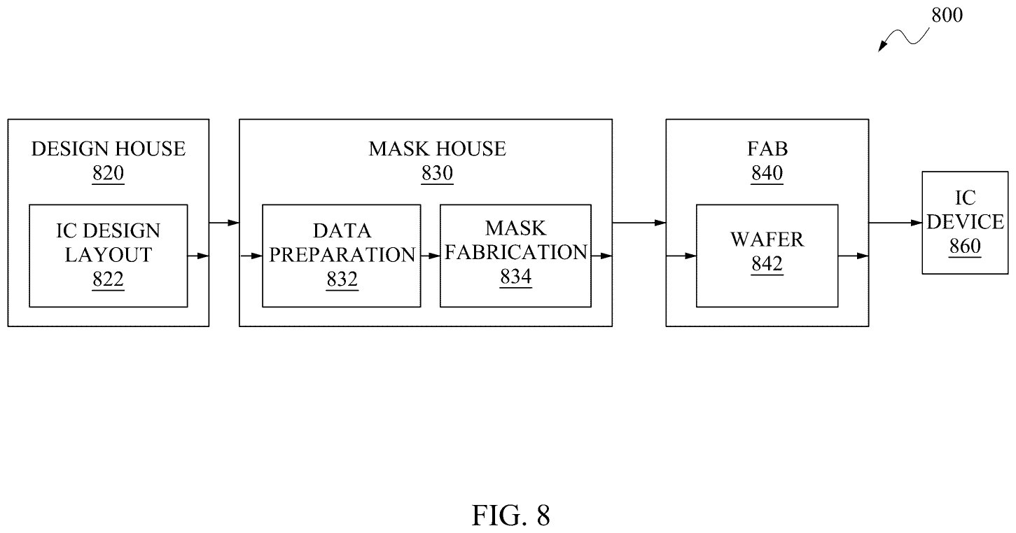

FIG. 8 is a block diagram of an integrated circuit (IC)/semiconductor device manufacturing system 800, and an IC manufacturing flow associated therewith, in accordance with some embodiments of the present disclosure.

In FIG. 8, the IC manufacturing system 800 includes entities, such as a design house 820, a mask house 830, and an IC manufacturer/fabricator (“fab”) 840, that interact with one another in the design, development, and manufacturing cycles and/or services related to manufacturing an IC device (semiconductor device) 860 including at least one of the semiconductor devices of the data DT1 and DT2. The entities in system 800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 820, mask house 830, and IC fab 840 is owned by a single company. In some embodiments, two or more of design house 820, mask house 830, and IC fab 840 coexist in a common facility and use common resources.

The design house (or design team) 820 generates an IC design layout 822. The IC design layout 822 includes various geometrical patterns designed for the IC device 860. The geometrical patterns correspond to patterns of metal, oxide, or semiconductor layers that make up the various components of the IC device 860 to be fabricated. The various layers combine to form various IC features. For example, a portion of the IC design layout 822 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 820 implements a proper design procedure to form the IC design layout 822. The design procedure includes one or more of logic design, physical design or place and route. The IC design layout 822 is presented in one or more data files having information of the geometrical patterns. For example, the IC design layout 822 can be expressed in a GDSII file format or DFII file format.

The mask house 830 includes mask data preparation 832 and mask fabrication 834. The mask house 830 uses the IC design layout 822 to manufacture one or more masks to be used for fabricating the various layers of the IC device 860 according to the IC design layout 822. The mask house 830 performs the mask data preparation 832, where the IC design layout 822 is translated into a representative data file (“RDF”). The mask data preparation 832 provides the RDF to the mask fabrication 834. The mask fabrication 834 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 832 to comply with particular characteristics of the mask writer and/or requirements of the IC fab 840. In FIG. 8, the mask data preparation 832 and mask fabrication 834 are illustrated as separate elements. In some embodiments, the mask data preparation 832 and mask fabrication 834 can be collectively referred to as mask data preparation.

In some embodiments, the mask data preparation 832 includes optical proximity correction (OPC) which uses lithography enhancement techniques to compensate for image errors, such as those that can arise from diffraction, interference, other process effects and the like. OPC adjusts the IC design layout 822. In some embodiments, the mask data preparation 832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 832 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 834, which may undo part of the modifications performed by OPC in order to meet mask creation rules.

In some embodiments, the mask data preparation 832 includes lithography process checking (LPC) that simulates processing that will be implemented by the IC fab 840 to fabricate the IC device 860. LPC simulates this processing based on the IC design layout 822 to create a simulated manufactured device, such as the IC device 860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 822.

It should be understood that the above description of the mask data preparation 832 has been simplified for the purposes of clarity. In some embodiments, the mask data preparation 832 includes additional features such as a logic operation (LOP) to modify the IC design layout according to manufacturing rules. Additionally, the processes applied to the IC design layout 822 during the mask data preparation 832 may be executed in a variety of different orders.

After the mask data preparation 832 and during mask fabrication 834, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 834 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 840 is an IC fabrication entity that includes one or more manufacturing facilities for the fabrication of a variety of different IC products. In some embodiments, the IC fab 840 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BMO tracks, BMI tracks), and a fourth manufacturing facility may provide other services for the foundry entity.

The IC fab 840 uses the mask (or masks) fabricated by the mask house 830 to fabricate the IC device 860. Thus, the IC fab 840 at least indirectly uses the IC design layout 822 to fabricate the IC device 860. In some embodiments, a semiconductor wafer is fabricated by the IC fab 840 using the mask (or masks) to form the IC device 860. The semiconductor wafer 842 includes a silicon substrate or other proper substrate having material layers formed thereon. Semiconductor wafer further includes one or more of various doped regions, dielectric features, multilevel interconnects, and the like (formed at subsequent manufacturing steps).

Also disclosed is a method. The method includes: generating a distribution pattern according to driving sizes of logic gates of a first semiconductor device corresponding to first data; transforming the distribution pattern to distribution data; generating first characterization data of the first semiconductor device according to the first data; generating first estimated distribution data according to the first characterization data by a model; training the model according to the first estimated distribution data and the distribution data; and processing second characterization data by the trained model to generate second estimated distribution data. The second characterization data corresponds to a second semiconductor device different from the first semiconductor device.

Also disclosed is a method. The method includes: generating first characterization data and distribution data from first data which corresponds to a first semiconductor device; training a model by the first characterization data and the distribution data; and after the model is trained, processing second characterization data which corresponds to a second semiconductor device different from the first semiconductor device, to generate first estimated distribution data. The first characterization data is associated with pin capacitances, energy consumptions and energy leakages of the first semiconductor device, and the distribution data is associated with driving sizes of logic gates of the first semiconductor device.

Also disclosed is a system. The method includes a processor and a memory. The processor is configured to operate a model. The memory is configured to store weights of the model. The processor is further configured to: generate a distribution pattern according to first data of a first semiconductor device, transform the distribution pattern to distribution data, generate first characterization data according to the first data, train the model by the first characterization data and the distribution data, and estimate second characterization data of a second semiconductor device different from the first semiconductor device by the model. The distribution pattern comprises ratios of driving sizes of logic gates of the first semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
generating a distribution pattern according to driving sizes of logic gates of a first semiconductor device corresponding to first data;
transforming the distribution pattern to distribution data;
generating first characterization data of the first semiconductor device according to the first data;
generating first estimated distribution data according to the first characterization data by a model;
training the model according to the first estimated distribution data and the distribution data; and
processing second characterization data by the trained model to generate second estimated distribution data,
wherein the second characterization data corresponds to a second semiconductor device different from the first semiconductor device.

2. The method of claim 1, wherein the distribution pattern comprises a first ratio and a second ratio corresponding to a first driving size and a second driving size, respectively,
the first semiconductor device at least comprises first logic gates having the first driving size and second logic gates having the second driving size,
the first ratio is equal to a quantity of the first logic gates divided by a quantity of the logic gates of the first semiconductor device, and
the second ratio is equal to a quantity of the second logic gates divided by a quantity of the logic gates of the first semiconductor device.

3. The method of claim 2, wherein transforming the distribution pattern to the distribution data comprises:
calculating first probability numerical values corresponding to the second driving size according to the first ratio, the second ratio and a third ratio,
wherein the distribution data includes the first probability numerical values,
the third ratio corresponds to a third driving size, and
the first driving size, the second driving size, and the third driving size are different from each other.

4. The method of claim 2, wherein in response to the second driving size is larger than the first driving size, a pin capacitance of the second logic gates is larger than a pin capacitance of the first logic gate, an area of the second logic gates is larger than an area of the first logic gates, and an energy consumption of the second logic gates is larger than an energy consumption of the first logic gates.

5. The method of claim 1, wherein the first characterization data comprises factors corresponding to pin capacitances, energy consumptions and energy leakages of the logic gates of each of the driving sizes.

6. The method of claim 1, wherein generating the first estimated distribution data comprises:
processing the first characterization data by long short-term memory layers and dropout layers to generate the first estimated distribution data.

7. The method of claim 6, wherein
a quantity of the long short-term memory layers is three, and
a quantity of the dropout layers is three.

8. The method of claim 6, wherein training the model comprises:
generating a loss function according to a difference between the first estimated distribution data and the distribution data; and
adjusting weights of the long short-term memory layers to decrease the loss function.

9. The method of claim 8, wherein processing the second characterization data comprises:
after the weights are adjusted, processing the second characterization data by the long short-term memory layers, without processing the second characterization data by the dropout layers, to generate the second estimated distribution data.

10. A method, comprising:
generating first characterization data and distribution data from first data which corresponds to a first semiconductor device;
training a model by the first characterization data and the distribution data; and
after the model is trained, processing second characterization data which corresponds to a second semiconductor device different from the first semiconductor device, to generate first estimated distribution data,
wherein the first characterization data is associated with pin capacitances, energy consumptions and energy leakages of the first semiconductor device, and
the distribution data is associated with driving sizes of logic gates of the first semiconductor device.

11. The method of claim 10, wherein training the model comprises:
processing the first characterization data by the model to generate second estimated distribution data;
generating a loss function according to a difference between the second estimated distribution data and the distribution data; and
adjusting weights of the model according to decrease the loss function.

12. The method of claim 11, wherein processing the first characterization data comprises:
generating input data according to the first characterization data;
processing the input data by long short-term memory layers and dropout layers alternately, to generate intermediate data;
generating output data according to the intermediate data; and
generating the second estimated distribution data according to the output data.

13. The method of claim 12, wherein processing the second characterization data comprises:
after the weights are adjusted, processing the second characterization data by the long short-term memory layers, without processing the second characterization data by the dropout layers, to generate the first estimated distribution data.

14. The method of claim 10, further comprising:
generating distribution pattern from the first data; and
transforming the distribution pattern to the distribution data,
wherein the distribution pattern comprises a first ratio, a second ratio and a third ratio corresponding to a first driving size, a second driving size and a third driving size, respectively,
the first semiconductor device at least comprises first logic gates having the first driving size, second logic gates having the second driving size and third logic gates having the third driving size,
the first driving size, the second driving size and the third driving size are different from each other.

15. The method of claim 14, wherein transforming the distribution pattern to the distribution data comprises:
calculating first probability numerical values corresponding to the second driving size according to the first ratio, the second ratio and the third ratio,
wherein the distribution data includes the first probability numerical values,
the third driving size is larger than the second driving size, and
the second driving size is larger than the first driving size.

16. The method of claim 14, wherein
the first ratio is equal to a quantity of the first logic gates divided by a quantity of the logic gates of the first semiconductor device, and
the second ratio is equal to a quantity of the second logic gates divided by a quantity of the logic gates of the first semiconductor device.

17. A system, comprising:
a processor configured to operate a model; and
a memory configured to store weights of the model,
wherein the processor is further configured to:
generate a distribution pattern according to first data of a first semiconductor device,
transform the distribution pattern to distribution data,
generate first characterization data according to the first data,
train the model by the first characterization data and the distribution data, and
estimate second characterization data of a second semiconductor device different from the first semiconductor device by the model,
wherein the distribution pattern comprises ratios of driving sizes of logic gates of the first semiconductor device.

18. The system of claim 17, wherein the ratios comprises a first ratio and a second ratio corresponding to a first driving size and a second driving size, respectively,
the first semiconductor device at least comprises first logic gates having the first driving size and second logic gates having the second driving size,
the first ratio is equal to a quantity of the first logic gates divided by a quantity of the logic gates of the first semiconductor device, and
the second ratio is equal to a quantity of the second logic gates divided by a quantity of the logic gates of the first semiconductor device.

19. The system of claim 17, wherein the first characterization data comprises factors corresponding to pin capacitances, energy consumptions and energy leakages of the logic gates of each of the driving sizes.

20. The system of claim 17, wherein the processor is further configured to:
generate first estimated distribution data according to the first characterization data,
adjust weights of the model according to a difference between the first estimated distribution data and the distribution data, and
after the weights are adjusted, generating second estimated distribution data according to the second characterization data by the model.
